(19) United States
(12) Patent Application Publication
(10) Pub. No.: US 2026/0358445 A1
(43) Pub. Date: Nov. 12, 2026

(54) MAGNETIC SENSOR APPARATUS AND PRODUCTION METHOD FOR A MAGNETIC SENSOR APPARATUS

(71) Applicant: Robert Bosch GmbH, Stuttgart (DE)

(72) Inventors: Nico Kerber, Reutlingen (DE); David Slogsnat, Tuebingen (DE); Manuel Glas, Kirchentellinsfurt (DE)

(21) Appl. No.: 19/654,641

(22) Filed: Apr. 22, 2026

(30) Foreign Application Priority Data
May 9, 2025 (DE) 10 2025 117 841.0

(51) Int. Cl. G01R 33/09

(52) U.S. Cl. CPC G01R 33/098

(57) ABSTRACT

A magnetic sensor apparatus. The magnetic sensor apparatus includes a substrate which has a substrate surface and a layer structure at least partially covering the substrate surface; a sensor unit, monolithically integrated into the layer structure, using which at least one analog measured signal; an analog-to-digital converter monolithically integrated into the layer structure, using which the at least one analog measured signal or derived from the at least one analog measured signal can be converted into at least one digital signal; and at least one wire bond connection each having at least one electrical contact arranged on and/or in the layer structure, and a bond wire connected to the at least one electrical contact, via which the at least one digital signal can be forwarded to at least one lead frame contact.

### FIELD

The present disclosure relates to a magnetic sensor apparatus.

Likewise, the present disclosure relates to a production method for a magnetic sensor apparatus.

### BACKGROUND INFORMATION

FIG. 1 is a schematic representation of a conventional magnetic sensor, which is known to the applicant as internal related art. The magnetic sensor/magnetic field sensor schematically represented in FIG. 1 has a substrate 10 with a layer structure 12 covering a first surface 10a of the substrate 10.

Magnetoresistive elements of a sensor unit of the conventional magnetic sensor, by means of which at least one analog signal, with respect to a magnetic field strength of an external magnetic field along at least one specified measurement axis, is intended to be measurable, are integrated into a so-called sensor layer 14 of the layer stack 12. An evaluation unit of the conventional magnetic sensor, by means of which the at least one analog signal is intended to be evaluable for establishing a relevant measured value of the relevant magnetic field strength, is formed at least partially within a circuit layer 16 of the layer stack 12, which lies between the first substrate surface 10a and the sensor layer 14. A redistribution layer 18 additionally lies on a side of the layer stack 12 facing away from the layers 14 and 16. For electrical contacting, solder balls 20 are fastened on a side of the layer stack 12 facing away from the substrate 10. Additionally, a second substrate surface 10b of the substrate 10 facing away from the first substrate surface 10a is covered with a passivation layer 22.

### SUMMARY

The present disclosure provides a magnetic sensor apparatus and a production method for a magnetic sensor apparatus. According to an example embodiment, the magnetic sensor apparatus includes:
a substrate having a substrate surface and a layer structure at least partially covering the substrate surface;
a sensor unit monolithically integrated into the layer structure and formed with magnetoresistive elements, by means of which sensor unit at least one analog measured signal, with respect to a magnetic field strength of an external magnetic field along at least one specified measurement axis, is measurable in each case;
an analog-to-digital converter likewise monolithically integrated into the layer structure, by means of which converter the at least one analog measured signal or at least one analog signal derived from the at least one analog measured signal can be converted into at least one digital signal; and
at least one wire bond connection having at least one electrical contact arranged on and/or in the layer structure in each case, and one bond wire each connected to the at least one electrical contact, via which the at least one digital signal can be forwarded to at least one lead frame contact.

The present disclosure creates advantageous possibilities for facilitating integration of magnetic sensor apparatuses/magnetic field sensors into a device equipped therewith by reducing a maximum extent of the respective magnetic sensor apparatuses along a direction perpendicular to a substrate surface of its substrate at least partially covered with a layer structure. This can also be described in that the present disclosure provides a “narrow,” “plate-shaped” or “disc-shaped” configuration of the magnetic sensor apparatus according to the present disclosure with a comparatively small maximum height of the relevant magnetic sensor apparatus perpendicular to its maximum surface area. The magnetic sensor apparatus according to the present disclosure can therefore be easily mounted, in particular, in comparatively thin/narrow devices, such as increasingly thinner mobile devices, in particular smartphones, foldable phones, wearables or true-wireless headphones. Thus, the present disclosure can be used in a variety of ways. At the same time, upon the integration of the magnetic sensor apparatus according to the present disclosure into such a device, the magnetic sensor apparatus occupies such a “small amount of space” that comparatively large installation space remains for further applications.

A further advantage of the present disclosure includes that its implementation/realization is possible using techniques that do not increase, or barely increase, labor expenditure and the associated costs for producing the magnetic sensor apparatus according to the present disclosure. Techniques for implementing/realizing the present disclosure are, for example, equipping a sensor unit of the magnetic sensor apparatus according to the present disclosure with magnetoresistive elements, configuring the magnetic sensor apparatus according to the present disclosure as a digital magnetic sensor apparatus by equipping said apparatus with the analog-to-digital converter, integrating said converter into the layer structure of the magnetic sensor apparatus according to the present disclosure, and using at least one wire bond connection together with at least one lead frame contact instead of solder balls. In particular, omitting the solder balls of the conventional magnetic sensor explained above, the diameter of which solder balls is generally at least 200 μm (micrometers), contributes substantially to realization of the advantages described in the preceding paragraph herein.

In an advantageous example embodiment of the magnetic sensor apparatus, the substrate has, perpendicular to the substrate surface, a maximum layer thickness less than or equal to 200 μm (micrometers). This can be readily achieved by thinning down the substrate.

Preferably, the substrate has, in each cross-sectional plane oriented parallel to the substrate surface, a surface having a surface area less than or equal to 6 mm² (square millimeters).

This also facilitates the positioning of the embodiment of the magnetic sensor apparatus described here in the examples of devices listed above.

In a further advantageous example embodiment of the magnetic sensor apparatus, the substrate, the at least one wire bond connection and the at least one lead frame contact are at least partially overmolded with a mold compound to form a block. In the embodiment described here, the mold compound thus protects the magnetic sensor apparatus against damage, even if the magnetic sensor apparatus falls or if the magnetic sensor apparatus mechanically contacts a further component.

Preferably, the block has, perpendicular to the substrate surface, a maximum block thickness less than or equal to 300 μm (micrometers). By omitting solder balls, which are typically at least 200 μm (micrometers) high, the maximum block thickness of the block perpendicular to the substrate surface can thus be significantly reduced. Whereas block thicknesses/package heights below 300 μm (micrometers) typically cannot be achieved for conventional magnetic sensors, this disadvantage is remedied in the embodiment of the magnetic sensor apparatus described here. Alternatively or additionally, the block can have, in each cross-sectional plane oriented parallel to the substrate surface, a cross-sectional area having a cross-sectional surface area less than or equal to 9 mm² (square millimeters). This advantageously reduces space required for the magnetic sensor apparatus for integration of said apparatus into a device.

The block can, in particular, be a lead-frame package, a flat no-leads package and/or a SON package. Thus, the technology described here can be used in a variety of ways.

As an advantageous development, the analog-to-digital converter can be part of an evaluation unit monolithically integrated into the layer structure, which converter is configured and/or programmed in such a way that, by means of the evaluation unit, taking into consideration the at least one analog measured signal, a measured value of a relevant magnetic field strength of the external magnetic field along at least one specified spatial direction is determinable as the at least one digital signal. The example embodiment of the magnetic sensor apparatus described here can thus be used for a plurality of applications, such as eCompass applications, inter alia.

Preferably, by means of the evaluation unit, taking into consideration the at least one analog measured signal, the measured value of the relevant magnetic field strength of the external magnetic field along the at least one spatial direction is determinable within a relevant value range bounded by a lower limit value less than or equal to −2 mT and an upper limit value greater than or equal to 2 mT. Thus, the embodiment of the magnetic sensor apparatus described here is well suited for customary field ranges in eCompass applications.

Alternatively or additionally, by means of the evaluation unit, taking into consideration the at least one analog measured signal, one measured value each of the relevant magnetic field strength of the external magnetic field can be determinable for 3 spatial directions oriented orthogonally relative to one another. Thus, the magnetic sensor apparatus described here can be used for a so-called 3D magnetic field sensor.

Performing a corresponding production method for a magnetic sensor apparatus also creates the advantages explained above. It is expressly pointed out that the production method can be further developed according to the example embodiments of magnetic sensor apparatuses described above.

### BRIEF DESCRIPTION OF THE DRAWINGS

Further features and advantages of the present disclosure will be explained in the following with reference to the figures.

FIG. 1 is a schematic representation of a conventional magnetic sensor.

FIG. 2 is a schematic representation of an example embodiment of the magnetic sensor apparatus.

FIG. 3 shows a flow chart for explaining an example embodiment of the production method for a magnetic sensor apparatus.

### DETAILED DESCRIPTION OF EXAMPLE EMBODIMENTS

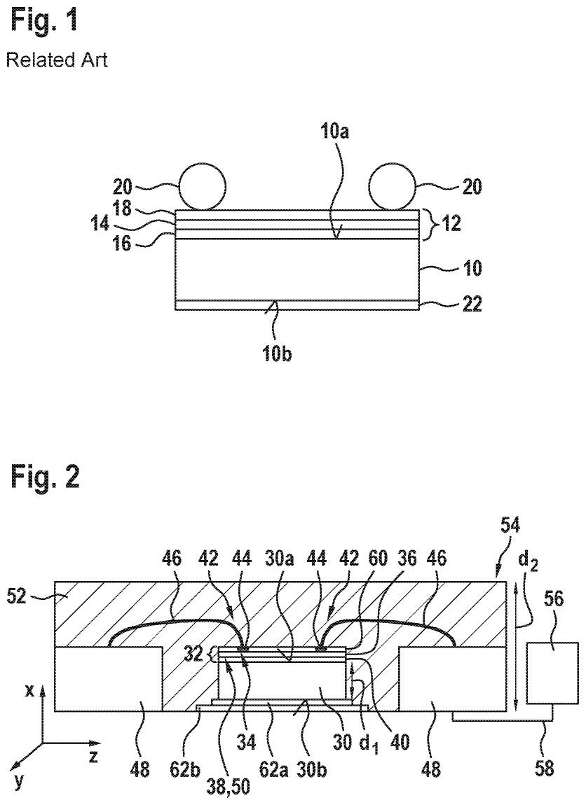

FIG. 2 is a schematic representation of an example embodiment of the magnetic sensor apparatus.

The magnetic sensor apparatus schematically represented in FIG. 2 has a substrate 30, such as a semiconductor substrate, in particular a silicon substrate. A layer structure 32 at least partially covering a first substrate surface 30a is formed on the first substrate surface 30a of the substrate 30. The substrate 30, including the layer stack 32 lying thereon, can also be understood as a so-called die/DIE, a chip or an unpackaged piece of a semiconductor wafer. A sensor unit 34 is monolithically integrated into the layer structure 32. This is realized in that magnetoresistive elements (not shown) of the sensor unit 34 are integrated into the layer structure 32, specifically into a sensor layer 36 as part of the layer structure 32. The magnetoresistive elements can be, e.g., at least one TMR element (tunnel magnetoresistance, magnetic tunnel resistance), at least one GMR element (giant magnetoresistance) and/or at least one AMR element (anisotropic magnetoresistive effect). Thus, the advantages of the types of magnetoresistive elements listed here can also be used for the sensor unit 34 formed with the respective magnetoresistive elements. TMR elements, in particular, are suitable for use in the magnetic sensor apparatus described here due to their high sensitivity.

The sensor unit 34 is understood to mean a unit by means of which at least one analog measured signal, with respect to a magnetic field strength of an external magnetic field along at least one specified measurement axis, is measurable/measured in each case.

For example, 3 or 4 measured signals, typically from 3 to 4 Wheatstone bridges of the sensor unit 34, can be measured as the at least one analog measured signal. It is pointed out that the at least one measurement axis of the sensor unit 34 does not necessarily mean along one of the spatial directions x, y and z graphically represented in FIG. 2. The configurability of the sensor unit 34 is also not limited to a particular number of measurement axes. The sensor unit 34 can have, e.g., one measurement axis, two measurement axes or three measurement axes. The magnetic sensor apparatus schematically represented in FIG. 2 is also formed with an analog-to-digital converter 38, which is likewise monolithically integrated into the layer structure 32. For example, the analog-to-digital converter 38 can be formed in a circuit layer 40 of the layer structure 32. If applicable, the circuit layer 40 is understood to mean a part of the layer structure 32. Advantageously, at least one application-specific integrated circuit (ASIC) can additionally be formed in the circuit layer 40 together with the analog-to-digital converter 38. In particular, the circuit layer 40 can be “sandwiched” between the sensor layer 36 and the first substrate surface 30a. By means of the analog-to-digital converter 38, the at least one analog measured signal or at least one analog signal derived from the at least one analog measured signal can be/is converted into at least one digital signal.

Due to being equipped with the analog-to-digital converter 38, the magnetic sensor apparatus described here is a digital magnetic sensor apparatus/a digital magnetic field sensor. Such a sensor type has, compared with an analog sensor, the advantage that the at least one digital signal obtained by means of the analog-to-digital converter 38 is more “robust” with respect to interference influences compared with a “corresponding analog signal.” Additionally, the monolithic integration of the analog-to-digital converter 38 into the layer structure 32 can be performed comparatively easily.

As can be recognized in FIG. 2, the magnetic sensor apparatus can therefore also be formed with at least one wire bond connection 42, wherein the at least one wire bond connection 42 is formed in each case with at least one electrical contact 44 arranged on and/or in the layer structure 32 and one bond wire 46 each connected to the at least one electrical contact 44. The at least one bond wire 46 can, for example, be a gold, aluminum or copper bond wire. The at least one electrical contact 44 is preferably a bond pad 44. A gold bond pad or aluminum bond pad can be used as the at least one bond pad 44 in each case. The at least one electrical contact 44 can, in particular, be integrated into the layer structure 32. Although this is not graphically represented in FIG. 2, an electrical connection, typically a so-called “via”, can extend from each electrical contact 44 through parts of the layer structure 32 up to the circuit layer 40 and possibly also into the circuit layer 40 in each case.

By means of the at least one wire bond connection 42, the at least one digital signal can be/is forwarded to at least one lead frame contact 48. The at least one lead frame contact 48 can also in each case be referred to as a lead frame contact. In particular, the at least one bond wire 46 can be connected at its end facing away from the layer structure 32 to the associated lead frame contact 48 (e.g., in the form of a further wire bond connection). The configuration of the at least one wire bond connection 42 described here facilitates reducing a maximum extent of the magnetic sensor apparatus along a first spatial direction x oriented perpendicular to the first substrate surface 30a of the substrate 30. Thus, the magnetic sensor apparatus of FIG. 2 is characterized, compared with the related art described above, by omission of solder balls. Whereas the use of solder balls in the related art described above significantly increases the maximum extent thereof along the first spatial direction x, this disadvantage is overcome by means of the at least one wire bond connection 42. Therefore, the magnetic sensor apparatus of FIG. 2 can be comparatively easily integrated into relatively thin devices, such as smartphones, foldable phones, wearables and/or true-wireless headphones. This can also be described in that the magnetic sensor apparatus described here can be formed with a low “height,” which enables better/freer positioning of said apparatus in a device having a low “overall height.”

Preferably, the substrate 30 has, along the first spatial direction x extending perpendicular to the first substrate surface 30a, a maximum layer thickness di less than or equal to 200 μm (micrometers). For this purpose, the substrate 30 can be correspondingly thinned down. The maximum layer thickness di of the substrate 30 along the first spatial direction x can, in particular, be less than or equal to 150 μm (micrometers), preferably less than or equal to 100 μm (micrometers), specifically less than or equal to 50 μm (micrometers). All of this can be used to reduce a maximum extent of the magnetic sensor apparatus along the first spatial direction x and thereby facilitate and/or improve the ability to install the magnetic sensor apparatus in a device.

Alternatively or additionally, the substrate 30 can also have, in each cross-sectional plane oriented parallel to the first substrate surface 30a and perpendicular to the first spatial direction x, a surface having a surface area less than or equal to 6 mm² (square millimeters). Preferably, the surface area of the surface of the substrate 30 in each cross-sectional plane oriented parallel to the first substrate surface 30a and perpendicular to the first spatial direction x is less than or equal to 5 mm² (square millimeters), for example less than or equal to 4 mm² (square millimeters), in particular less than or equal to 3 mm² (square millimeters), specifically less than or equal to 2 mm² (square millimeters). Even if the surface area of the surface of the substrate 30 in the relevant cross-sectional plane oriented parallel to the first substrate surface 30a and perpendicular to the first spatial direction x is 0.04 mm² (square millimeters), the first substrate surface 30a still provides sufficient “space” for the layer structure 32 with the sensor unit 34 monolithically integrated therein and the analog-to-digital converter 38 likewise monolithically integrated therein.

As can be recognized in FIG. 2, the substrate 30, the at least one wire bond connection 42 and the at least one lead frame contact 48 can be at least partially overmolded with a mold compound 52 to form a block/package 54. The block 54 can in particular be a lead-frame package, a flat no-leads package and/or an SON package (small-outline no-leads package). Overmolding the substrate 30, the at least one wire bond connection 42 and the at least one lead frame contact 48 at least partially with the mold compound 52 can also be described as molding. A plastics compound can be used as a mold compound 52. By means of the at least partial overmolding with the mold compound 52, the substrate 30, the at least one wire bond connection 42 and the at least one lead frame contact 48 are embedded into the mold compound 52 so that the substrate 30, the at least one wire bond connection 42 and the at least one lead frame contact 48 are reliably protected against mechanical and thermal stresses.

The block 54 can, in particular, be cuboid-shaped or disc-shaped. A particular advantage of the block 54 lies in that it can have, along the first spatial direction x oriented perpendicular to the first substrate surface 30a, a comparatively small maximum block thickness d2. For example, the block 54 can have, along the first spatial direction x, a maximum block thickness da less than or equal to 300 μm (micrometers), in particular less than or equal to 250 μm (micrometers). Preferably, the maximum block thickness d2 lies in a range between 130 μm (micrometers) and 250 μm (micrometers).

Accordingly, the block 54 can have, in each cross-sectional plane oriented parallel to the first substrate surface 30a and perpendicular to the first spatial direction x, a cross-sectional area having a cross-sectional surface area less than or equal to 9 mm² (square millimeters). If desired, the cross-sectional surface area of the block 54 in each cross-sectional plane oriented parallel to the first substrate surface 30a and perpendicular to the first spatial direction x can be less than or equal to 7 mm² (square millimeters), in particular less than or equal to 5 mm² (square millimeters), specifically less than or equal to 3 mm² (square millimeters). Due to the advantageous features of the block 54 described above, its cross-sectional surface area in each cross-sectional plane oriented parallel to the first substrate surface 30a and perpendicular to the first spatial direction x can also be equal to 0.2 mm² (square millimeters).

As an advantageous development, the magnetic sensor apparatus can also be equipped with an evaluation unit 50 only schematically represented in FIG. 2. The evaluation unit 50 is preferably monolithically integrated into the layer structure 32. Specifically, the evaluation unit 50 can be integrated into the circuit layer 40. If applicable, the analog-to-digital converter 38 is part of the evaluation unit 50. The evaluation unit 50 is advantageously configured and/or programmed in such a way that, by means of the evaluation unit 50, a measured value of a relevant magnetic field strength of the external magnetic field along at least one specified spatial direction x, y and z is determinable/determined as the at least one digital signal.

The determination of the at least one measured value is carried out by means of the evaluation unit 50 taking into consideration the at least one analog measured signal. If a spatial direction x, y or z is present at an inclination angle unequal to 0° and less than 90° relative to a plurality of measurement axes of the sensor unit 34, the plurality of analog measured signals of the respective measurement axes can also contribute to the measured value for this spatial direction x, y or z.

The evaluation unit 50 can comprise, e.g., at least one preamplifier and/or one microcontroller in addition to the analog-to-digital converter 38. If desired, one measured value each for all three spatial directions x, y and z oriented orthogonally relative to one another can also be determinable/determined by means of the evaluation unit 50.

Thus, the magnetic sensor apparatus described here can, in particular, be a 3D-magnetic sensor apparatus.

By means of corresponding configuration and/or programming of the magnetic sensor apparatus/the evaluation unit 50 thereof, it can also be ensured that a relevant value range/measurement range, within which the at least one measured value is reliably determinable, is bounded by a lower limit value less than or equal to −2 mT (millitesla) and an upper limit value greater than or equal to 2 mT (millitesla). Therefore, the magnetic sensor apparatus described here can advantageously also respond well to the presence of external interference sources associated with significantly higher interference fields. Thus, the magnetic sensor apparatus is particularly suitable for eCompass applications. Preferably, the lower limit value is less than or equal to −2.5 mT (millitesla), for example less than or equal to −3 mT (millitesla), in particular less than or equal to −3.5 mT (millitesla), preferably less than or equal to −4 mT (millitesla), specifically less than or equal to −4.5 mT (millitesla), preferably less than or equal to −5 mT (millitesla). Correspondingly, the upper limit value of the relevant value range/measurement range can be greater than or equal to 2.5 mT (millitesla), for example greater than or equal to 3 mT (millitesla), in particular greater than or equal to 3.5 mT (millitesla), advantageously greater than or equal to 4 mT (millitesla), specifically greater than or equal to 4.5 mT (millitesla), preferably greater than or equal to 5 mT (millitesla).

If desired, an external unit (host) 56 can be electrically connected to the at least one lead frame contact 48 by means of at least one line 58. The at least one line 58 can in particular be referred to as a digital data interface 58 or as a (digital) host interface. The digital data interface 58 can be realized, e.g., as an I2C interface (Inter-Integrated Circuit), as an SPI interface (Serial Peripheral Interface) or as an I3C interface (SenseWire). Optionally, parts of the evaluation unit 50, such as the microcontroller, can also be realized in the external unit 56.

The layer structure 32 can also have an (optional) passivation layer 60. Preferably, the passivation layer 60 lies on a side of the sensor layer 36 facing away from the circuit layer 40 within the layer structure 32. Optionally, the at least one electrical contact 44 can lie “directly on” the passivation layer 60 or at least partially within the passivation layer 60.

As can be recognized in FIG. 2, the substrate 30 can be fastened, at a second substrate surface 30b facing away from the first substrate surface 30a, to at least one support layer 62a and 62b.

The at least one support layer 62a and 62b can, e.g., be a die pad, a die attach pad, a die paddle, a die attach film and/or a die attach adhesive. However, the graphical representation of the support layers 62a and 62b in FIG. 2 is to be interpreted merely as exemplary. The at least one support layer 62a and 62b can likewise also be omitted. In particular, if applicable, the second substrate surface 30b can be surrounded by the mold compound 52.

Alternatively, the second substrate surface 30b can also be part of an outer surface of the block 54. In this way as well, the maximum block thickness d2 of the block 54 oriented along the first spatial direction x (extending perpendicular to the first substrate surface 30a) can be minimized.

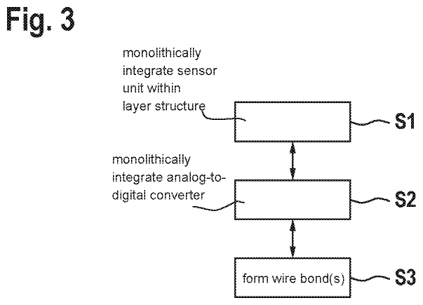

FIG. 3 shows a flow chart for explaining an embodiment of the production method for a magnetic sensor apparatus.

By means of the production method described below, the magnetic sensor apparatus of FIG. 2 can, e.g., be produced. However, the ability to perform the production method is not limited to production of this magnetic sensor apparatus.

In a method step S1 of the production method, a sensor unit with magnetoresistive elements is monolithically integrated within a layer structure that at least partially covers a substrate surface of a substrate. The method step S1 is performed so that, by means of the (finished) sensor unit, at least one analog measured signal, with respect to a magnetic field strength of an external magnetic field along at least one specified measurement axis, can be/is measured in each case.

As method step S2 of the production method, an analog-to-digital converter likewise monolithically integrated within the layer structure is formed. The analog-to-digital converter is formed so that the at least one analog measured signal or at least one analog signal derived from the at least one analog measured signal can be/is converted into at least one digital signal by means of the analog-to-digital converter.

Additionally, in a method step S3 of the production method, at least one wire bond connection having at least one electrical contact arranged on and/or in the layer structure in each case, and one bond wire each connected to the at least one electrical contact is formed. By performing method step S3, it is ensured that the at least one digital signal can be/is forwarded via the at least one wire bond connection to at least one lead frame contact.

Accordingly, performing the production method described here also produces the advantages explained above. The method steps S1 to S3 can be performed in any order, partially overlapping in time or simultaneously.

1-11. (canceled)

12. A magnetic sensor apparatus, comprising:
a substrate having a substrate surface, and a layer structure at least partially covering the substrate surface;
a sensor unit monolithically integrated into the layer structure and formed with magnetoresistive elements, the sensor unit configured to measure at least one analog measured signal with respect to a magnetic field strength of an external magnetic field along each of at least one specified measurement axis;
an analog-to-digital converter monolithically integrated into the layer structure, the analog-to-digital converter configured to convert into at least one digital signal one of the at least one analog measured signal, or at least one analog signal derived from the at least one analog measured signal; and
at least one wire bond connection, each including at least one electrical contact arranged on and/or in the layer structure, and each including a bond wire, connected to the at least one electrical contact, wherein via the at least one wire bond connection, the at least one digital signal can be forwarded to at least one lead frame contact.

13. The magnetic sensor apparatus according to claim 12, wherein the substrate has, perpendicular to the substrate surface, a maximum layer thickness less than or equal to μm.

14. The magnetic sensor apparatus according to claim 12, wherein the substrate has, in each cross-sectional plane oriented parallel to the substrate surface, a surface having a surface area less than or equal to 6 mm².

15. The magnetic sensor apparatus according to claim 12, wherein the substrate, the at least one wire bond connection, and the at least one lead frame contact are at least partially overmolded with a mold compound to form a block.

16. The magnetic sensor apparatus according to claim 15, wherein the block has, perpendicular to the substrate surface, a maximum block thickness less than or equal to 300 μm.

17. The magnetic sensor apparatus according to claim 15, wherein the block has, in each cross-sectional plane oriented parallel to the substrate surface, a cross-sectional area having a cross-sectional surface area less than or equal to 9 mm².

18. The magnetic sensor apparatus according to claim 15, wherein the block is at least one of: a lead-frame package, a flat no-leads package, or a small-outline no-leads (SON) package.

19. The magnetic sensor apparatus according to claim 12, wherein the analog-to-digital converter is part of an evaluation unit monolithically integrated into the layer structure, the evaluation unit configured to determine a measured value of a relevant magnetic field strength of the external magnetic field along at least one specified spatial direction as the at least one digital signal, taking into consideration the at least one analog measured signal.

20. The magnetic sensor apparatus according to claim 19, wherein the evaluation unit is configured to determine the measured value of the relevant magnetic field strength of the external magnetic field along the at least one spatial direction within a relevant value range bounded by a lower limit value less than or equal to −2 mT and an upper limit value greater than or equal to 2 mT, taking into consideration the at least one analog measured signal.

21. The magnetic sensor apparatus according to claim 20, wherein the evaluation unit is configured to determine one measured value each of the relevant magnetic field strength of the external magnetic field for 3 spatial directions oriented orthogonally relative to one another, taking into consideration the at least one analog measured signal.

22. A production method for a magnetic sensor apparatus, comprising the following steps:
forming a monolithically integrated sensor unit with magnetoresistive elements within a layer structure at least partially covering a substrate surface of a substrate, the sensor unit configured to measure at least one analog measured signal with respect to a magnetic field strength of an external magnetic field along each of at least one specified measurement axis;
forming an analog-to-digital converter monolithically integrated within the layer structure, the analog-to-digital converter configured to convert into at least one digital signal one of the at least one analog measured signal, or at least one analog signal derived from the at least one analog measured signal; and
forming at least one wire bond connection, each including at least one electrical contact arranged on and/or in the layer structure, and each including a bond wire connected to the at least one electrical contact in such a way that the at least one digital signal can be forwarded via the at least one wire bond connection to at least one lead frame contact.
